(19) United States
(12) Patent Application Publication
(10) Pub. No.: US 2026/0123508 A1
(43) Pub. Date: Apr. 30, 2026

(54) INTEGRATED CIRCUIT ATTACHMENT MECHANISMS

(71) Applicant: Intel Corporation, Santa Clara, CA (US)

(72) Inventors: Terry William GILMORE, Ridgefield, WA (US); Casey THIELEN, Chandler, AZ (US)

(21) Appl. No.: 19/430,372

(22) Filed: Dec. 23, 2025

Related U.S. Application Data
(60) Provisional application No. 63/827,024, filed on Jun. 20, 2025.

(51) Int. Cl. H10W 72/60; H10D 80/30; H10W 46/00; H10W 70/60; H10W 72/00; H10W 90/00; H10W 90/10

(52) U.S. Cl. CPC H10W 72/634; H10W 46/301; H10W 72/07636; H10W 72/834; H10W 90/764; H10D 80/30; H10W 70/611; H10W 90/10; H10W 90/734

(57) ABSTRACT

Various aspects relate to mechanisms for coupling a three-dimensional semiconductor cube to a host substrate including a plurality of substrate communication points. The three-dimensional semiconductor cube includes a plurality of cube communication points corresponding to the plurality of substrate communication points and at least one mounting mechanism that couples the three-dimensional semiconductor cube to the host substrate.

### CROSS-REFERENCE TO RELATED APPLICATION

This application claims priority to U.S. Provisional Application No. 63/827,024 filed on Jun. 20, 2025, the contents of which is fully incorporated herein by reference.

### BACKGROUND

In general, three-dimensional heterogeneous integration involves combining different types of semiconductor implementations, such as logic, memory, and radio frequency, on a single package. Approaches to three-dimensional heterogeneous integration techniques face significant limitations in the physical attachment of structures, especially when these structures are rotated, edge-mounted, or otherwise oriented outside of traditional face-down packaging geometries. As integration density increases and dies are assembled in non-planar or cube-style configurations, conventional bonding and or attachment techniques become difficult to scale, align, or rework. Specifically, existing methods fail to address several challenges. First, mechanical retention of three-dimensional stacked cubes is unreliable. Precision lateral alignment of multiple cube structures to the host substrate in the presence of thermal expansion are difficult, especially with respect to die bow, or pitch variation. Controlled mechanical dampening and adhesive stabilization is difficult to achieve. Accordingly, there is a need for new mechanical, structural, and adhesive attachment strategies tailored for edge oriented three-dimensional heterogeneous integration of cubes, enabling secure, repeatable, and high yield integration across varying substate types and die topologies.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the proposed configuration. In the following description, various aspects are described with reference to the following drawings, in which:

FIG. 1 shows an example three-dimensional heterogeneous integrated cube attached to a host substrate by way of a cantilever snap-fit latch mechanism integrated into or anchored on the host substrate;

FIG. 2 shows a grid of location frames configured to support a plurality of three-dimensional heterogeneous integration cubes;

FIG. 3 shows a grid of location frames configured to support a plurality of three-dimensional heterogeneous integration cubes and to be accurately positioned on a host substrate using corner locators at the surface of a fabric die;

FIG. 4 shows an example location frame having location frame die touch offs at a bottom surface of the location frame;

FIG. 5 shows an example three-dimensional heterogeneous integrated cube attached to a host substrate by way of an example adhesive providing a non-zero Z-dimension height gap between the cube and substrate;

FIG. 6 shows an example diagram of a kirizuma (or gable roof) contact forming a layered electrical and mechanical interface with a dielectric base structure;

FIG. 7 shows another example diagram of a kirizuma contact forming a layered electrical and mechanical interface with contacts extended;

FIG. 8 shows another example diagram of a kirizuma contact forming a layered electrical and mechanical interface from underneath with contacts extended through a dielectric base structure;

FIG. 9 shows an example diagram of a kirizuma contact coupled with a three-dimensional memory cube;

FIG. 10 shows an example top-hat packaging device for a dual-load mechanical and thermal interface system providing independent control of compression forces within a three-dimensional heterogeneous integration package;

FIG. 11 shows an example top-hat packaging device for a dual-load mechanical and thermal interface system with secondary integrated heat spreader removed;

FIG. 12 shows an example top-hat packaging device for a dual-load mechanical and thermal interface system with socket and package with primary and secondary top-hat integrated heat spreader removed;

FIG. 12A shows an example TG-contact as a vertically-oriented electrical and mechanical interface designed to provide high-density signal, power, and ground pathways between adjacent three-dimensional heterogeneous integration structures;

FIG. 13 shows an example hot-key architecture as an electromechanical attachment system designed to secure three-dimensional heterogeneous integration structures to a host interposer or substrate while providing power and signal delivery and precise alignment during installation;

FIG. 14 shows an example hot-key architecture module being emplaced onto an interposer;

FIG. 15 shows an example hot-key architecture module being emplaced onto an interposer with the hot-key yoke removed and bails exposed;

FIG. 16 shows a collection of example hot-key architecture modules integrated into a system-on-a-chip (SoC);

FIG. 17 shows an example interleaved hot-key architecture module as an electromechanical attachment system that extends the hot-key architecture using interleaved bails and a cinched yoke to improve electrical distribution, thermal uniformity, and structural balance in three-dimensional heterogeneous integration assemblies;

FIG. 18 shows an example interleaved hot-key architecture module with a top bail transparent for purposes of illustration;

FIG. 19 shows an example interleaved hot-key architecture module with electrical isolation between interleaved bails;

FIG. 20 shows an example interleaved hot-key architecture module with electrical isolation between interleaved bails in side view;

FIG. 21 shows an example interleaved hot-key architecture module with electrical isolation between interleaved bails with a cinched yoke;

FIG. 22 shows an example interleaved hot-key architecture module with electrical isolation between interleaved bails with the cinched yoke removed;

FIG. 23 shows an example tether-key architecture module as an electromechanical attachment system that secures three-dimensional heterogeneous integration structures to a host using tensioned conductive straps;

FIG. 24 shows an example tether-key architecture module with yoke removed;

FIG. 25 shows an example quiver-lock architecture module as a mechanical and electrical attachment architecture for three-dimensional heterogeneous integration structures deploying vertically oriented spring contacts (arrows) to form both mechanical and electrical coupling;

FIG. 26 shows an example quiver-lock architecture module seated in an interposer;

FIG. 27 shows an example slice-lock architecture module as a mechanical alignment and retention architecture that uses an additional silicon slice to create precision mating features between a three-dimensional heterogeneous integration structure and a host interposer or substrate;

FIG. 28 shows an example slice-lock architecture module before being seated;

FIG. 29 shows an example vee-lock architecture module as a mechanical and electrical docking interface designed to align and secure three-dimensional heterogeneous integration structures to a host substrate or interposer;

FIG. 30 shows an example vee-lock architecture module prior to seating;

FIG. 31 shows an example vee-lock architecture module in side view;

FIG. 32 shows an example vee-lock architecture module with optional secondary side alignment mechanism;

FIG. 33 shows example contacts with reduced impedance;

FIG. 34 shows example side contacts capable of applying steady contact force;

FIG. 35 shows an example Muninn dock system which provides a precision mechanical alignment and electrical docking interface for three-dimensional heterogeneous integration structures, using combination of alignment pins, pin blocks, and keyed guides;

FIG. 36 shows an example Muninn dock system without a coarse alignment mechanism; and

FIG. 37 shows an example Muninn dock system before seating.

### DESCRIPTION

The following detailed description refers to the accompanying drawings that show, by way of illustration, specific details and aspects in which the proposed configuration may be practiced. These aspects are described in sufficient detail to enable those skilled in the art to practice the proposed configuration. Other aspects may be utilized and structural, logical, and electrical changes may be made without departing from the scope of the proposed configuration. The various aspects are not necessarily mutually exclusive, as some aspects may be combined with one or more other aspects to form new aspects. Various aspects are described in connection with methods and various aspects are described in connection with devices (e.g., a memory module, a computing system). However, it is understood that aspects described in connection with methods may apply in a corresponding manner to the devices, and vice versa.

In an embodiment, a cantilever snap-fit latch mechanism integrated into or anchored on the host substrate, enables tool-free mechanical retention of a three-dimensional heterogeneous integration cube through flexible-locking latches during placement. In addition to mechanical attachment, the latch structures can deliver power and signal interfaces directly though the latch body to the three-dimensional integrated circuit structures themselves. In this embodiment, the cantilever snap-fit latch may be visible at the mechanical interface between the cube and the host substrate if not covered by molding or encapsulant. Latch arms consistent with various aspects may be fabricated from any material and include integrated conductive traces that align with the complementary structures embedded in the sidewall of the cube. This allows power and signal transfer if no physical attachment at the face of cube, while also providing a mechanical hold that supports both assembly and field operation. The latch geometry may be tuned to account for die tolerance, insertion force, and dynamic stress.

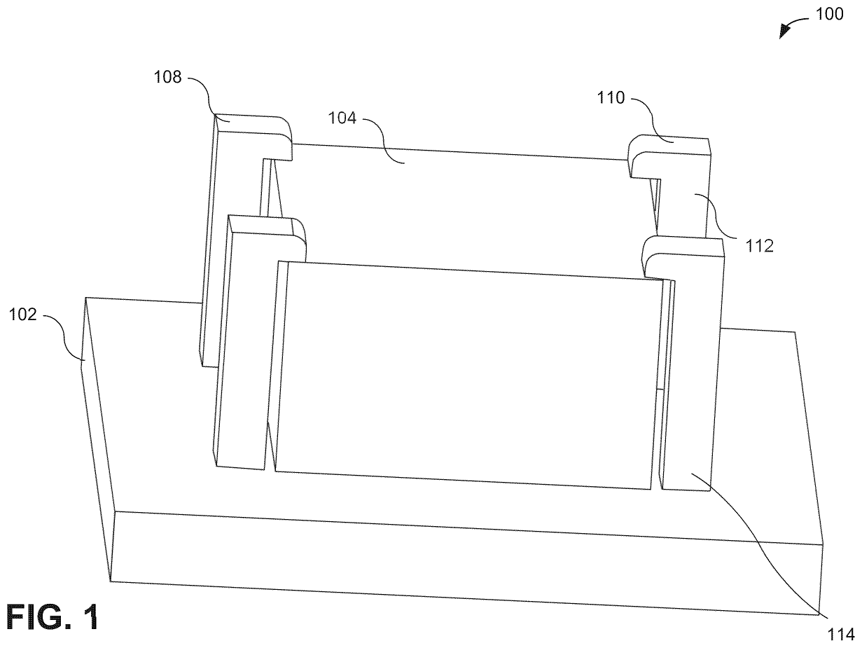

FIG. 1 shows an assembly 100 illustrating exemplary three-dimensional heterogeneous integrated cube 104 attached to host substrate 102 by way of cantilever snap-fit latch mechanism 108 integrated into or anchored on host substrate 102. As shown in FIG. 1, certain embodiments may employ cantilever snap-fit latch mechanism 108 integrated into or mounted on the host substrate to physically secure three-dimensional heterogeneous integration cube 104 during assembly. The latch includes compliant beam 112 that bends outward when cube 104 is inserted, then springs back to hold cube 104 in place without solder, reflow, or adhesives. In some embodiments, latch mechanism 108 has an upper grip 110 that may grasp a top surface of cube 104. Alternatively, upper grip may grasp cube 104 from the side, holding cube 104 in place by friction or by way of a recess or other notch (not shown) in a lateral side of cube 104. These latches are capable of being designed to attach to any part of the cube for signaling and power contacts. Such a solder-free mounting structure is useful when “wireless” or induction-based communication is employed between components of cube 104 and host substrate 102.

Associated stacked memory chiplets may be rotated 90 degrees to form a Z Axis Memory stack (ZAM). In this arrangement, communication between the stacked memory die and an associated host die is within a short distance. In addition, by using inductive coupling as the communication mechanism, the interface becomes contactless. On a host side, planar inductors can be fabricated. On the stacked memory side, novel paradigms for providing communication inductors are disclosed herein.

In various embodiments, stacking and bonding multiple wafers (or chiplets) can significantly enhance logic and memory density of an integrated circuit. A chiplet is a small, modular, and independently testable unit of a larger integrated circuit, designed to be combined with other chiplets to create a more complex system. Vertical vias that run through such layered wafers create connections between stacked dies. These vertical vias through the stacked dies can create vertical inductors by connecting the top and bottom ends using redistribution layers (RDL), which can be used as an inductive interface of such a memory chip. Additionally, a single thick die with through silicon vias (TSV) can connect a top and bottom using RDLs to form vertical multi-turn inductor coils. Such an approach allows associated chiplets to interface through chiplet edges using vertical inductor coils.

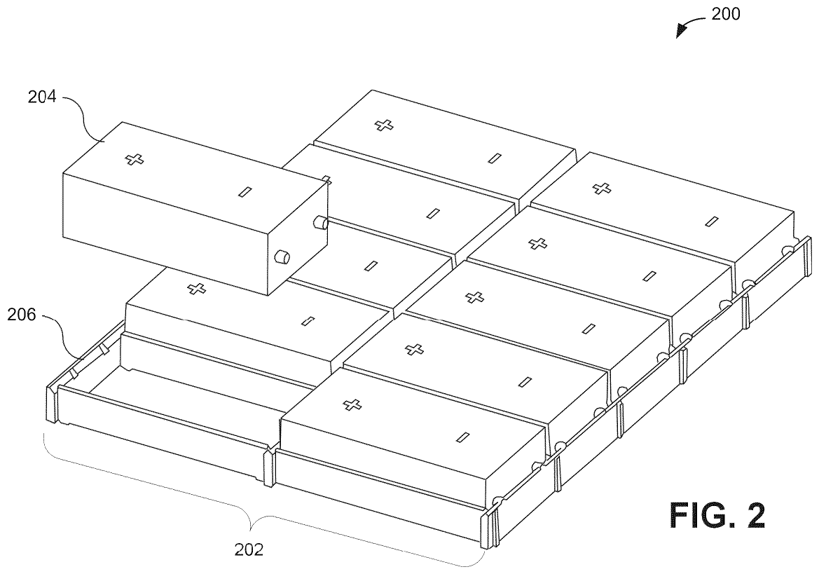

FIG. 2 depicts a combination 200 of three-dimensional integrated circuits in an exemplary grid 202 of location frames 206 configured to support a plurality of three-dimensional heterogeneous integration cubes 204. In these embodiments, a metal location frame affixed to the perimeter of cube 204, designed to interface precisely with substrate-grown locator features for guided, self-aligning placement, allows the three-dimensional heterogeneous integration cube to fit within the designated locations. In some embodiments the cube is configured to fit within a location frame with a press fit, meaning once inserted into a location frame an inserted cube will be retained in the location frame by mechanical pressure and friction. In addition to mechanical attachment, the frame can deliver power and signal interfaces directly though the frame body to the three-dimensional integrated circuit structures themselves. In this embodiment, the metal location frame may be visible at the mechanical interface between the cube and the host substrate if not covered by molding or encapsulant.

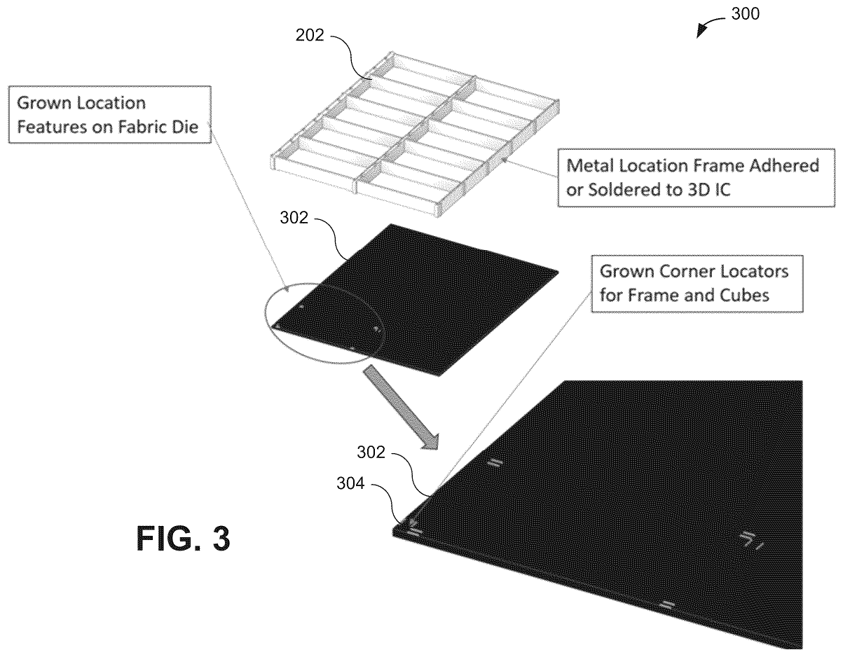

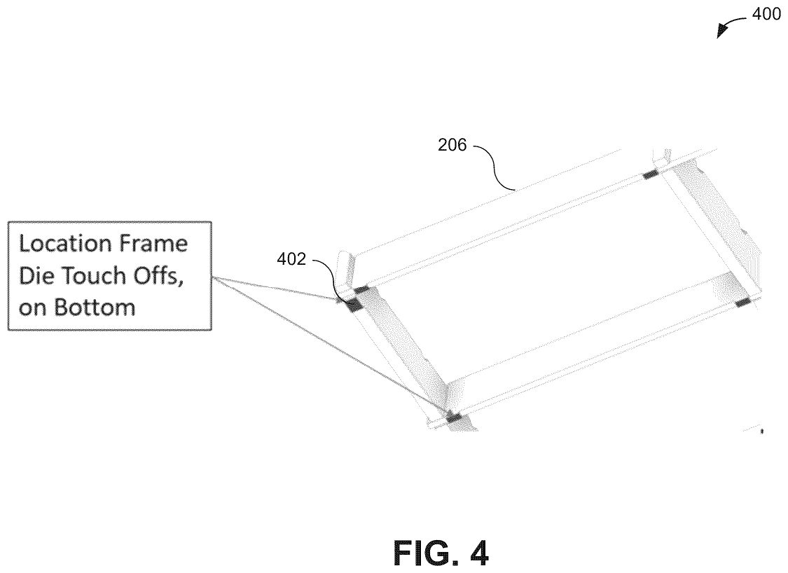

As shown in FIG. 2-4, the invention includes a metallic alignment frame affixed to the edge or perimeter of the cube, which mates with per-formed locator features on the host substrate. FIG. 3 shows a grid 202 of location frames configured to support a plurality of three-dimensional heterogeneous integration cubes (not shown) and to be accurately positioned on a host substrate 302 using corner locators 304 at the surface of host substrate 302. These features can be grown through additive processes or formed through patterned/etch steps in the substrate. The frame and locator system enables precise lateral alignment of the cube, ensuring edge connections remain co-planar and within tolerances. In addition to alignment, the metal frame may serve as a power or signal conduit, leveraging edge contacts or embedded structures. This mechanism is especially suited for large multi-cube arrays or stacked modules that must be field replaceable or assembled without active tool intervention. FIG. 4 shows an exemplary location frame 206 having location frame die touch offs 402 at a bottom surface of the location frame. Die touch offs 402 may be employed to interface with corner locators 304 as depicted in FIG. 3.

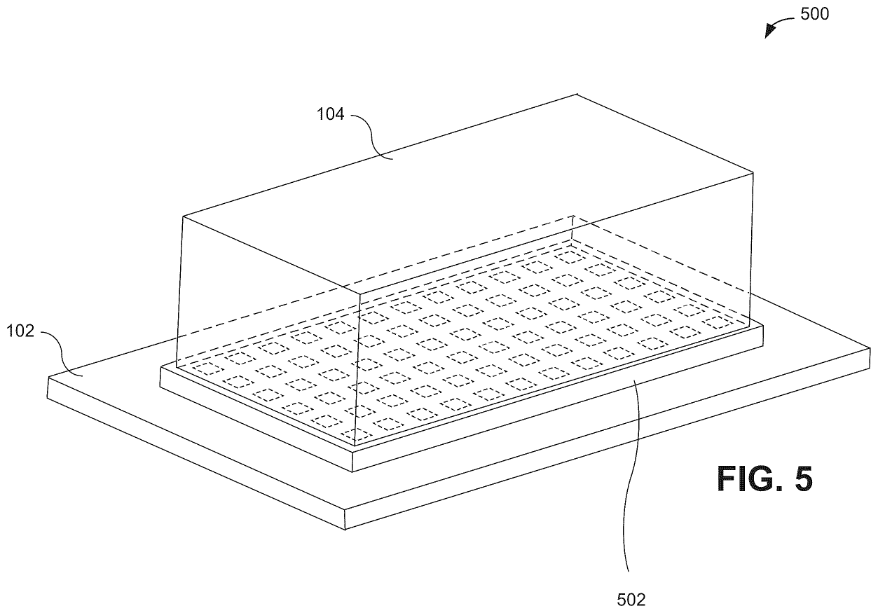

FIG. 5 shows a combination 500 of an exemplary three-dimensional heterogeneous integrated cube 104 attached to a host substrate 102 by way of an exemplary adhesive 502 providing a non-zero Z height gap between the cube and substrate. In this embodiment, an adhesive attachment offers mechanical stabilization through a bonding strategy, where glue is selectively applied around the base of the cube while preserving the necessary gap between cube and host die faces without interfering with an associated wireless communication interface. In this embodiment, adhesive 502 beneath the cube may be any type of glue or adhesive that is compatible for use in connection with semiconductors. In some embodiments, die attach film (DAF) may be employed.

These attachment mechanisms provide a scalable, modular foundation for attaching edge-oriented three-dimensional heterogeneous integration structures to a system on a chip (SOC) without a need for conventional solder attachments that require reflow, underfill, or mechanical tooling. By combining mechanical retention, precision alignment, signal and power coupling, these solutions improve workability and enable high-density integration across diverse packaging substrates. This allows the fabrication of more compact, serviceable, and heterogeneous systems while expanding the design envelope for chiplet-based architectures and vertically stacked compute structures.

As shown in FIG. 5, in certain embodiments, a three-dimensional heterogeneous integration cube may be stabilized on the host substrate using a selectively applied adhesive layer that bonds the base of the cube to the substrate without obstructing the communication interface. A controlled gap is intentionally maintained between the cube and host die to allow for wireless communication. The adhesive may be patterned using stencil printing, screen printing, or jet dispensing to surround the active communication zones without interfering with the signal transfer. This glue application approach provides mechanical stability, vibration damping, and thermal buffering without introducing outgassing, stress concentrations, or underfill-related failure modes.

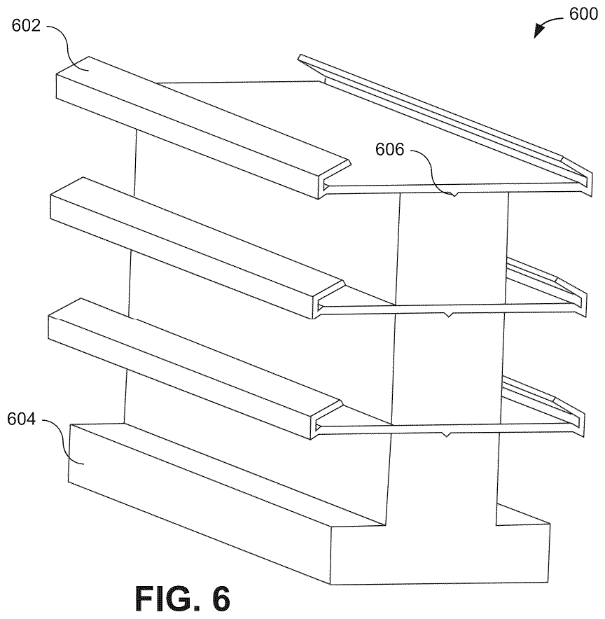

FIG. 6-9 show example diagrams 600 to 900 including kirizuma contacts (or gable roof structures) forming a layered electrical and mechanical interface with a dielectric base structure 604. A kirizuma contact (gable roof contact) is a layered electrical and mechanical interface designed for edge-mounted three-dimensional heterogeneous integration (3DHI) structures. A kirizuma contact enables reliable signal and power transfer while also serving as a mechanical retention mechanism. The contact includes a stack of conductive contact fascia layers 602, each corresponding to a specific electrical function (power/ground/sideband/signal), separated by electrically isolating blocks that maintain signal integrity between layers.

Both the conductive and insulating elements may be keyed together by way of key (or chuck) 606, ensuring precise layer-to-layer alignment and preventing assembly misalignment. When a 3DHI cube is inserted, the cube's edge contacts press against the kirizuma fascia surfaces 602, which flex slightly to maintain a stable electrical connection under thermal and mechanical stress. The isolating blocks 604 help to distribute insertion force evenly, reducing localized stress and protecting the integrity of the structure.

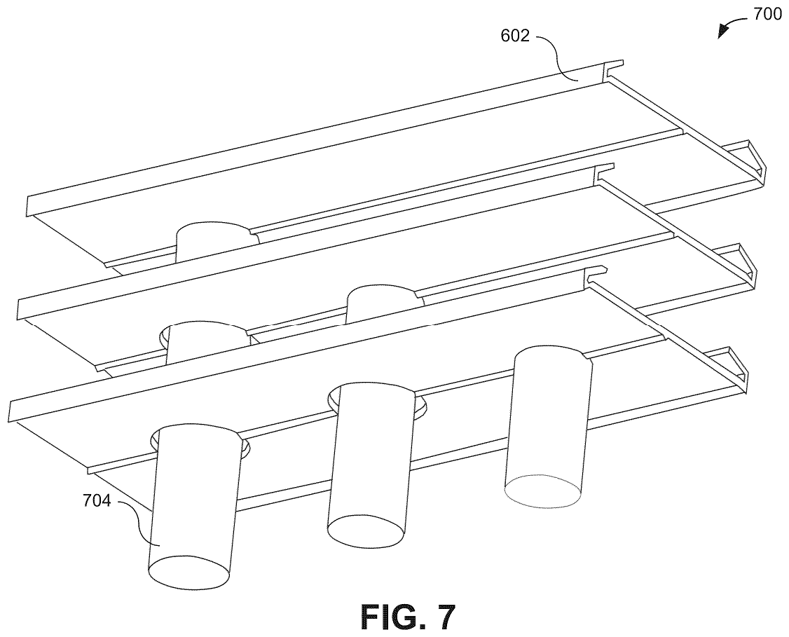

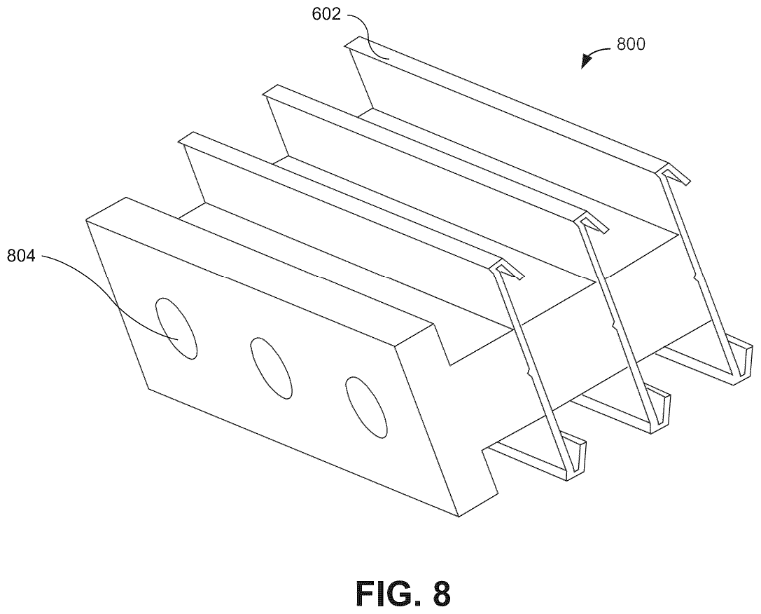

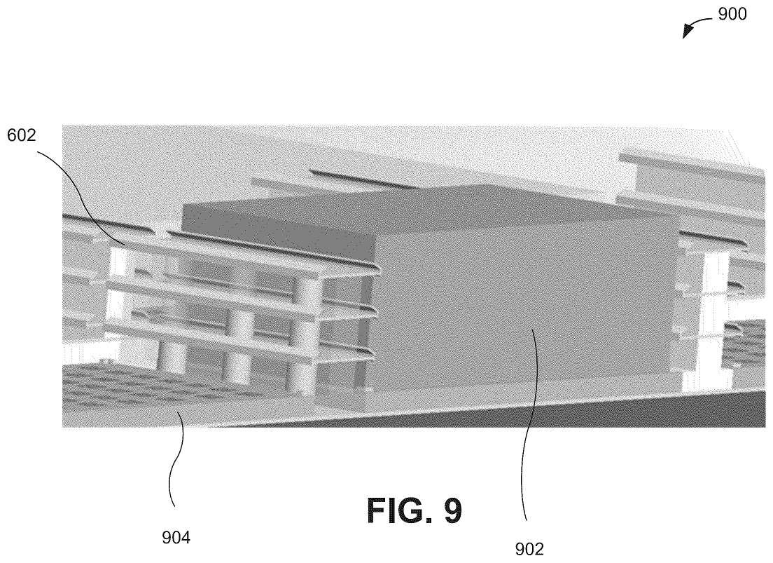

Kirizuma contact assemblies can be produced using standard forming, molding, or additive methods. Conductive layers may be made from spring metals or plated copper alloys, while isolating components may be fabricated from thermoplastics, ceramics, or other dielectric materials compatible with semiconductor packaging environments. The design supports scalable manufacturing through stamping, lamination, or co-molding, enabling integration into sockets, interposers, or package-level retention assemblies. FIG. 7 shows another example diagram 700 of a kirizuma contact forming a layered electrical and mechanical interface with contact posts 704 extended through the fascia layers 602. As shown in diagram 700, contact posts 704 extend through subsequent fascia layers 602 with a gap that electrically isolates contact posts 704 from the fascia layers 602 through which the contact posts 704 pass. FIG. 8 shows another example diagram 800 of a kirizuma contact forming a layered electrical and mechanical interface from underneath with contact terminations 804 extended through a dielectric base structure. Contact terminations 804 may be soldered to an interposer or a host substrate. FIG. 9 shows an example diagram 900 of a kirizuma contact coupled with a three-dimensional memory cube 902, which may be mounted on an interposer 904.

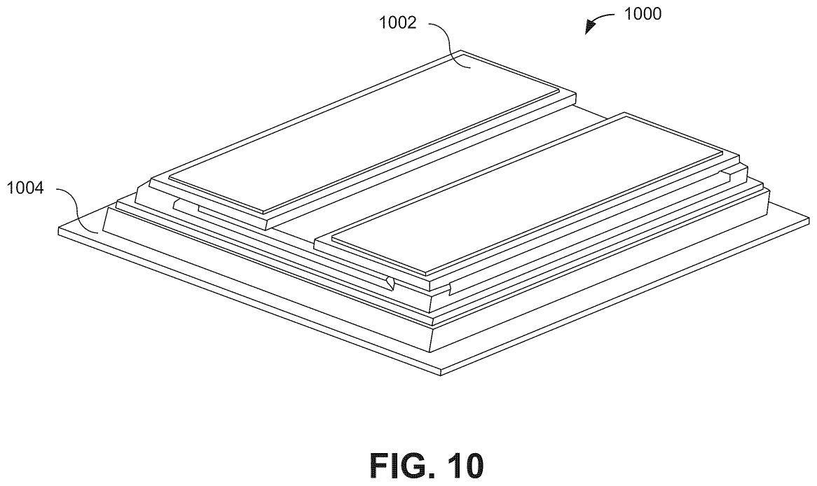

FIGS. 10, 11, and 12 depict example top-hat packaging devices 1000 and 1100 for dual-load mechanical and thermal interface systems providing independent control of compression forces within a three-dimensional heterogeneous integration package. The structure includes a primary heat spreader 1004 that receives package-level thermal load from an independent loading mechanism (ILM) device or socket mechanism, and a secondary “top hat” integrated heat spreader (HIS) positioned above the 3DHI cubes 1102. In various aspects, a secondary lid 1002 may be mechanically decoupled from the primary heat spreader 1004 and supported by compliant or adjustable stand-of structures, allowing it to apply a controlled, localized force directly to the 3DHI structures without influencing the rest of the package.

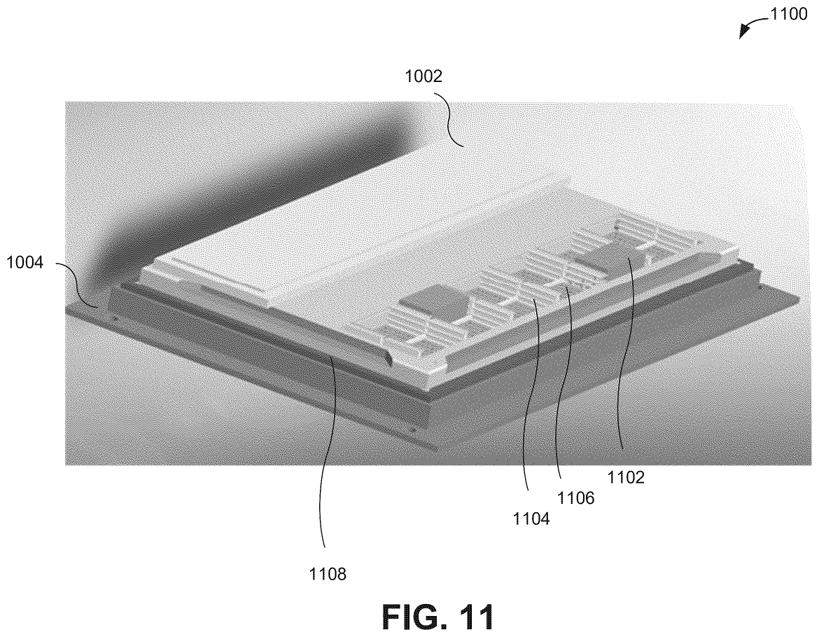

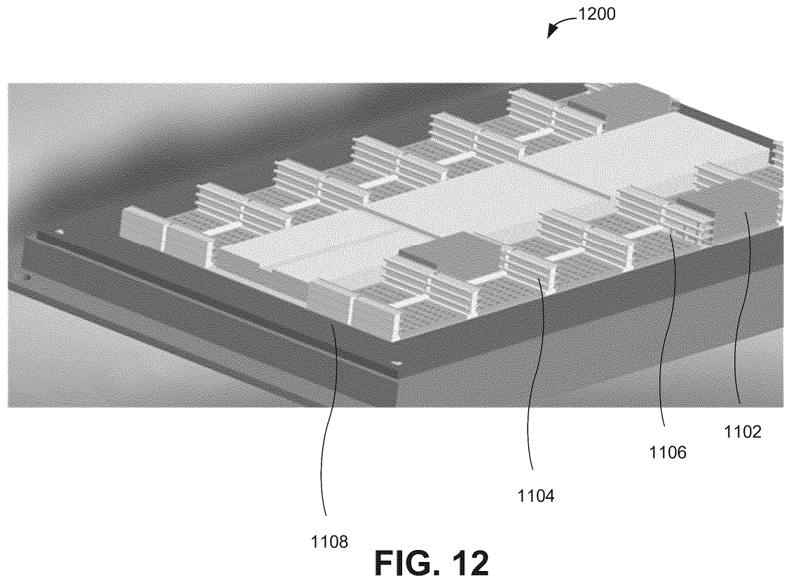

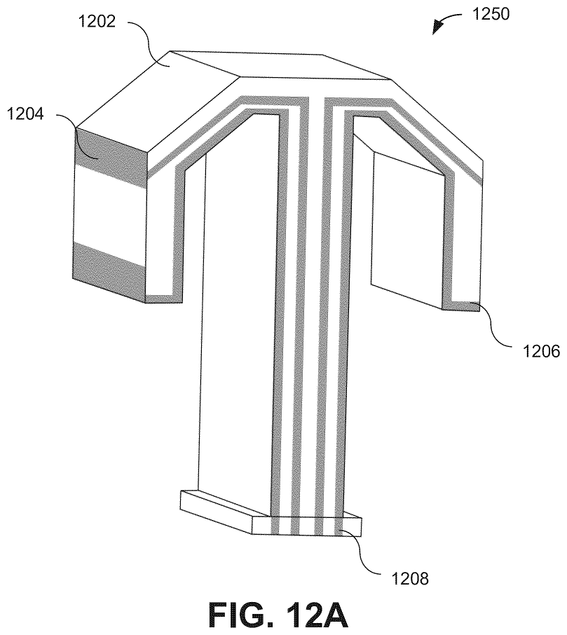

Such a configuration enables finer management of preload and contact pressure between cubes 1102, interposers 1106, and substrates, reducing mechanical stress on delicate three-dimensional interconnects while improving thermal coupling. The decoupled force path allows separate optimization of cooling and retention across heterogeneous elements, supporting more reliable high-density stacking alignment. Such systems may be fabricated using standard lid-forming or co-molding processes, with compliant interfaces made from thermally conductive foams, springs, or polymer pads to tune the mechanical response. FIG. 11 shows an example top-hat packaging device 1100 for a dual-load mechanical and thermal interface system with secondary integrated heat spreader removed. FIG. 12 shows an example top-hat packaging device 1200 for a dual-load mechanical and thermal interface system with socket and package with primary and secondary top-hat integrated heat spreader 1002 removed.

FIG. 12A shows an example TG-contact device 1250 as a vertically-oriented electrical and mechanical interface designed to provide high-density signal, power, and ground pathways 1204, 1206, and 1208 between adjacent three-dimensional heterogeneous integration structures. A TG-contact is a vertically oriented electrical and mechanical interface designed to provide high-density signal, power, and ground pathways between adjacent 3DHI structures while minimizing a lateral contact footprint on packages, interposers, or printed circuit board floors. Such structures may include multiple conductive layers laminated or compressed vertically into a “T” shaped profile, where an upper crossbar provides broad electrical contact surfaces to packages, and a lower stem delivers vertical structural and conductive support to host substrates. A base of a TG-contact may be mechanically anchored or solder-bonded to a substrate or interposer to provide structural stability and current continuity.

Such a geometry increases available routing and component area on interposers or substrates by confining a significant portion of a conductive path within a vertical stem, allowing tighter module spacing and reduced parasitic coupling. Successive conductive layers may be separated by thin dielectric films or isolating laminations, maintaining electrical isolation between different signal domains while ensuring mechanical rigidity when 3DHI structures are compressed together. In various aspects, a laminated body of a TG-contact may be formed through co-molding, diffusion bonding, additive metal layering, and plated or coated to enhance reliability and wear resistance.

Such a design enables direct, repeatable engagement with 3DHI edge pads or sockets and can be scaled in thickness, height, or material composition to tune electrical resistance, capacitance, impedance or mechanical stiffness. By consolidating vertical conduction into a narrow, laminated body, such a contact supports high-density interconnects across stacked chiplets or 3DIC structures while reducing routing congestion, mechanical stress, and thermal mismatch within a package environment.

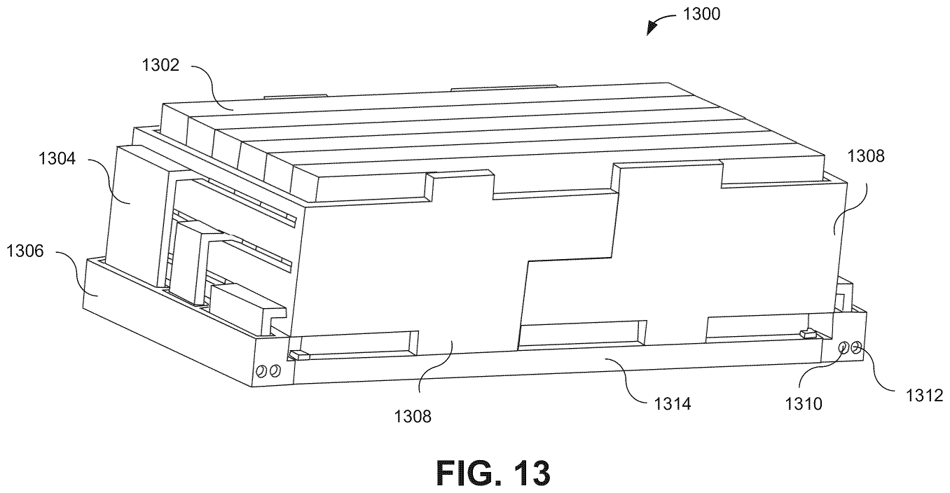

FIGS. 13, 14, and 15 depict example hot-key architecture diagrams 1300, 1400, and 1500 depicting an electromechanical attachment system. Such systems secure three-dimensional heterogeneous integration structures to a host interposer or substrate 1314 while providing power and signal delivery and precise alignment during installation. The depicted systems includes bails 1304 positioned along a side of a 3DHI structure, yokes 1308 that mechanically capture the bails 1304 to control preload, and a cauldron assembly 1306 containing conductive coils surrounding localized solder buckets on the host side. The bails 1304 make contact with routed power, ground, and signal conductors on edges of slices 1302, by way of lateral cube conductors 1504, while the cauldron 1306 generates focused heat though coil-induced resistive or inductive heating to selectively melt the solder within the buckets. This enables each cube to be aligned, seated, and permanently anchored without exposing the surrounding package to excessive thermal stress.

This geometry reduces substrate-level routing congestion and allows multiple cubes to be placed in dense arrays by localizing both mechanical retention and electrical distribution at the perimeter of each structure. Electrical isolation between VCC, VSS, and signal conductors is maintained through internal dielectric segmentation along the bail and bucket assemblies. Following alignment, the molten solder wets bails 1304 or lower contact pads and solidifies into a mechanically rigid and electrically conductive joint. Such an assembly may be fabricated using laminated metal structures, machined alloys, or co-molded dielectric metal composites, and the coils or heating elements may be embedded, wrapped, or plated depending on process constraints. By combing localized heating, edge-based power delivery, and mechanical capture, such systems enables high-density, high-current attachment of 3DHI structures with minimal thermal exposure to neighboring dies or package regions. Access points 1310 and 1312 provide external access to couple power, i.e., positive voltage, ground, and/or signal connections of slices 1302. A grouping of slices 1302 form a cube.

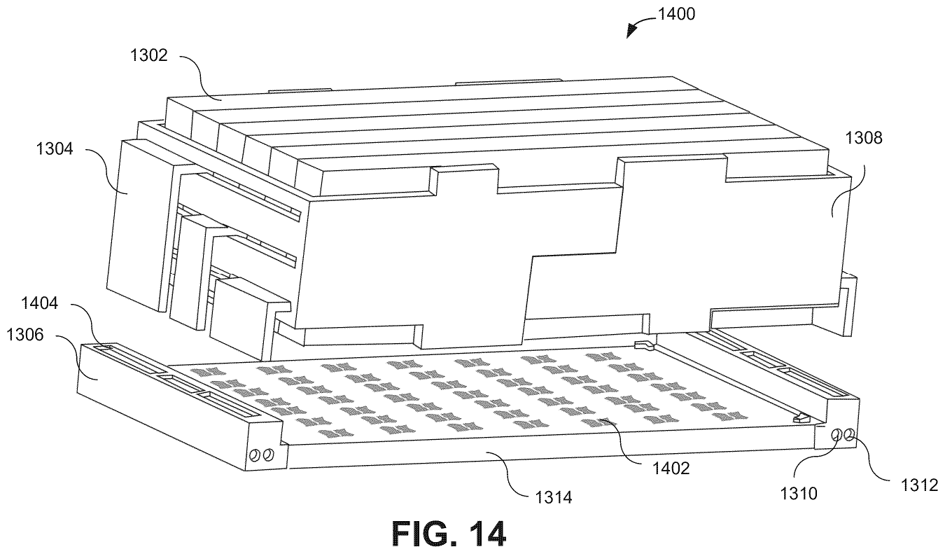

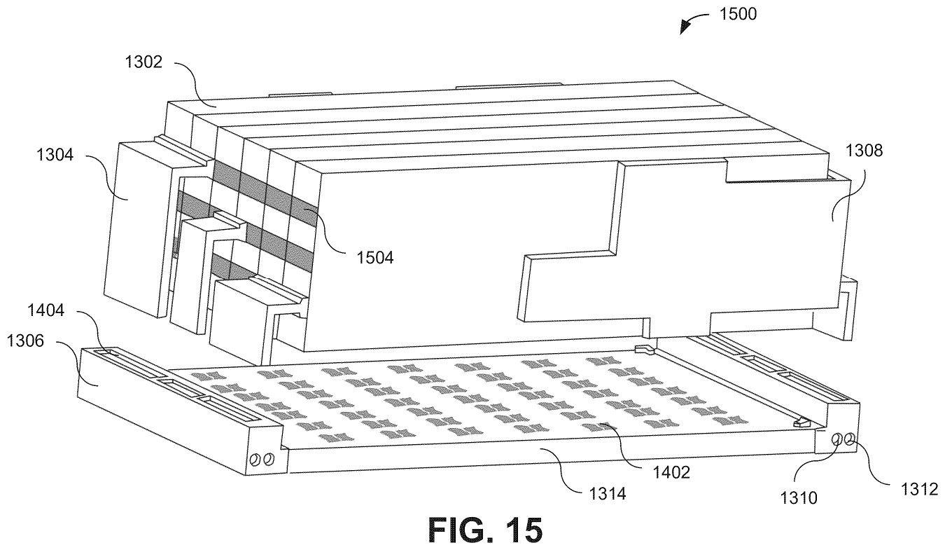

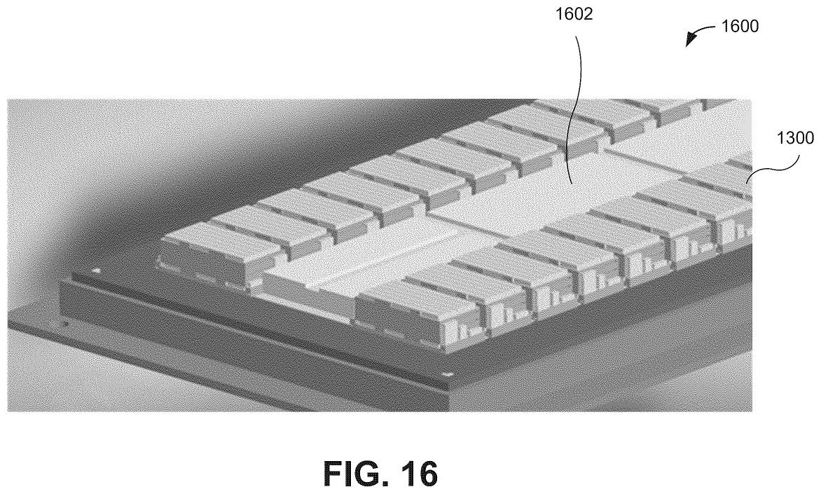

FIG. 14 shows an example hot-key architecture module 1400 being emplaced onto an interposer. Upon emplacement the system is fixedly soldered to interposer 1314, when solder within buckets 1404 is heated so that bails 1304 can be inserted into molten solder within buckets 1404. FIG. 15 shows an example hot-key architecture module 1500 being emplaced onto an interposer with the hot-key yoke removed and bails 1304 exposed. With bails 1304 exposed, contacts with lateral cube conductors 1504 may be more easily observed. Contacts 1402 are provided in interposer 1314 so to mate with contacts from each of the slices 1302. FIG. 16 shows a collection 1600 of example hot-key architecture modules 1300 integrated with components 1602 into an overall system-on-a-chip (SoC). Contacts 1402 may be wired, i.e., physical electrical contact such as solder or pogo pins. Alternatively, contacts 1402 may be wireless contacts.

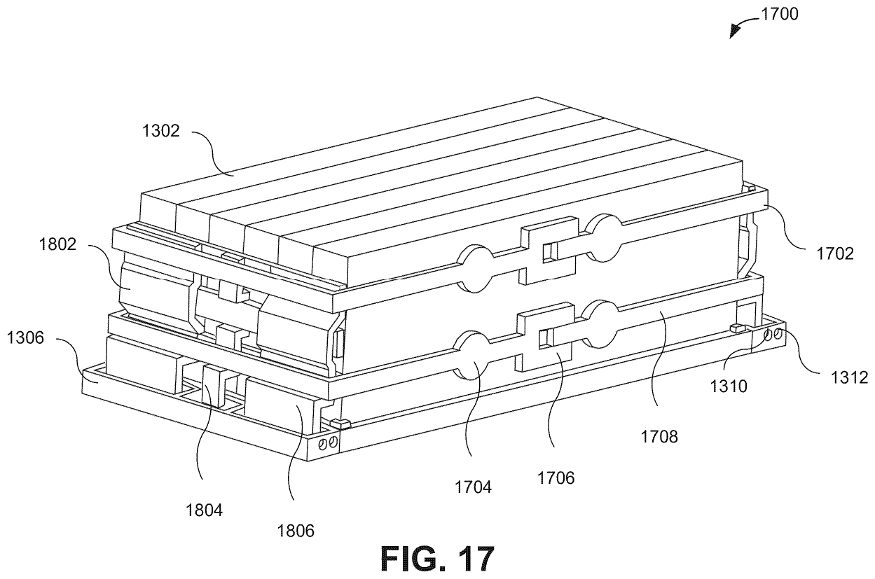

FIG. 17-22 show example interleaved hot-key architecture modules 1700 to 2200 as an electromechanical attachment system that extends the hot-key architecture using interleaved bails 1802, 1804, and 1806 and a cinched yoke 1702 to improve electrical distribution, thermal uniformity, and structural balance in three-dimensional heterogeneous integration assemblies. The interleaved hot-key architecture provides an electromechanical attachment system that extends the hot-key architecture of FIGS. 13, 14, and 15. Alternating bails 1802, 1804, and 1806 may be positioned along structure and interlocked within a dielectric mechanism, enabling multiple isolated power, ground, and signal paths within a compact footprint. Each bail is advantageously electrically insulated by thin dielectric separators 1808, while the cinched yoke applies uniform preload across the bails to prevent edge stress and maintain compression symmetry. The yoke halves 1706 and 1708 may be brought together using a precision machine (compressing circular portions 1704) and secured with adhesive or UV-cured resin to ensure permanent mechanical capture. In various aspects, a mechanical ratchet mechanism in yoke portion 1706 may allow cinching of the yoke halves with a zip-tie-type mechanism.

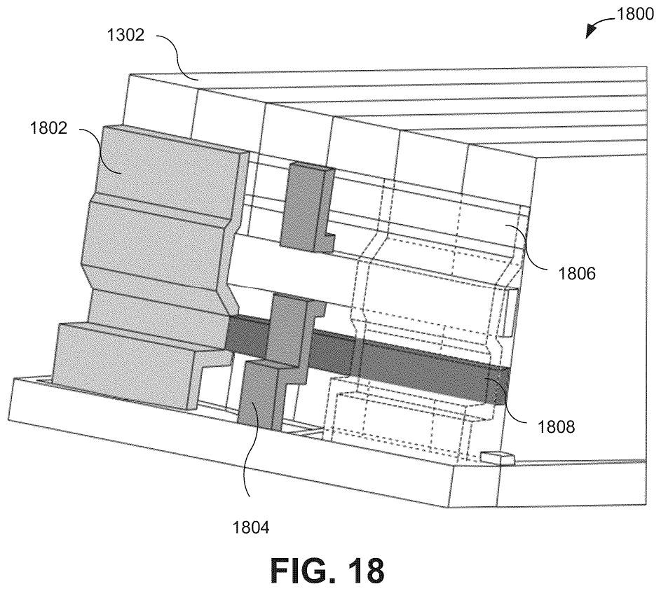

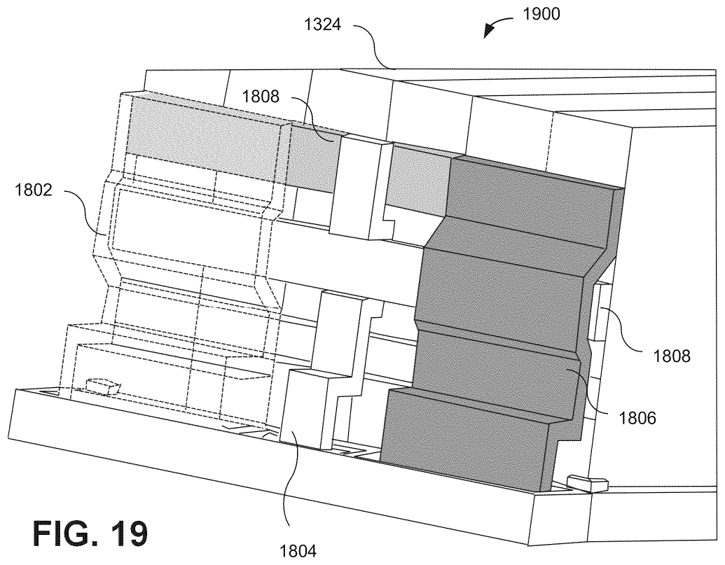

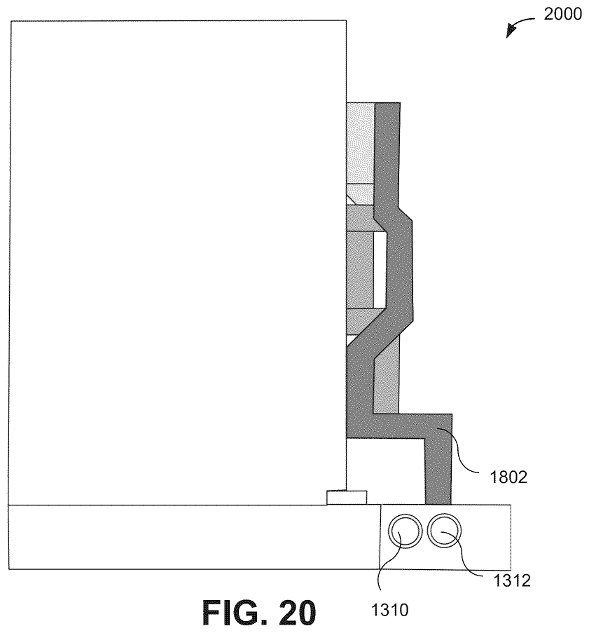

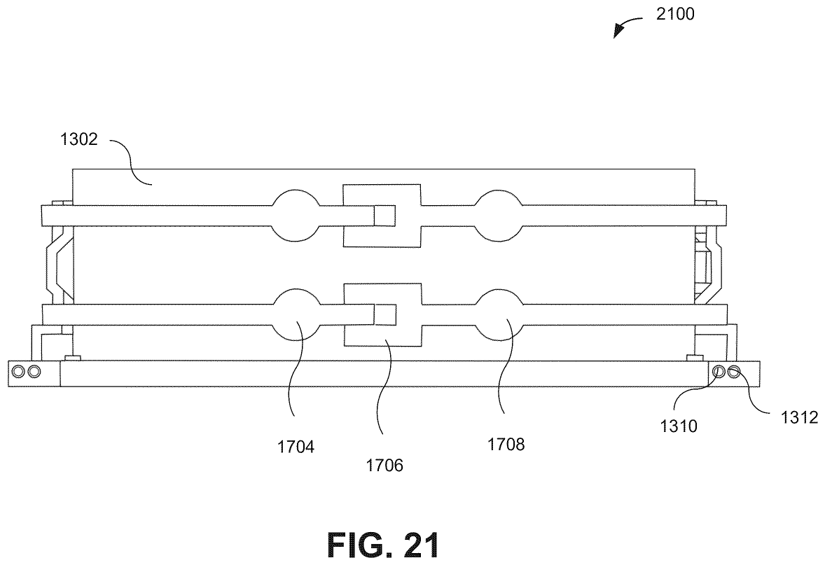

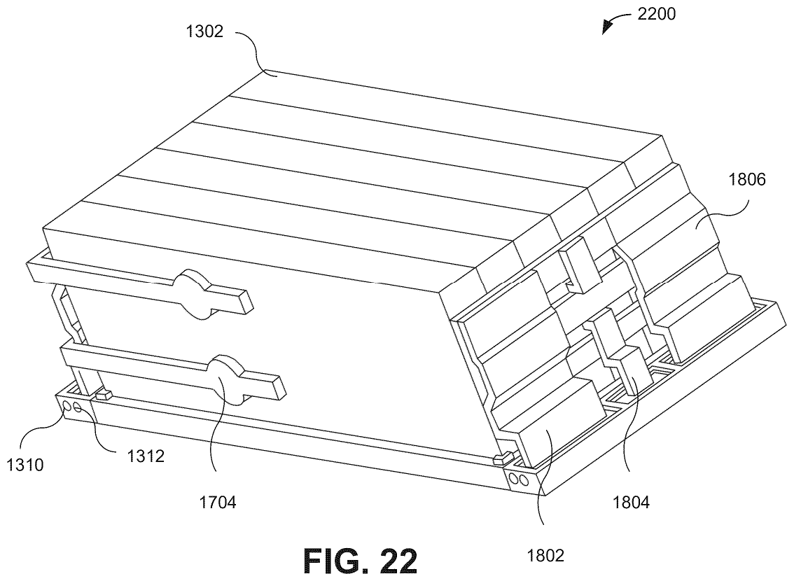

This interleaved structure increases contact density and current capacity while improving heat dissipation across three-dimensional cube interfaces. The cauldron 1306 at the base may provide localized inductive or resistive heating to reflow solder within solder buckets, locking the cube to the host interposer or substrate without heating surrounding regions. Such a design may be manufactured using laminated or machined conductive alloys, co-molded dielectric composites, or diffusion bonded laminations to support high-density 3DHI integration. FIG. 18 shows an example interleaved hot-key architecture module 1800 with a top bail transparent for purposes of illustration. FIG. 19 shows an example interleaved hot-key architecture module 1900 with electrical isolation between interleaved bails. FIG. 20 shows an example interleaved hot-key architecture module 2000 with electrical isolation between interleaved bails in side view. FIG. 21 shows an example interleaved hot-key architecture module 2100 with electrical isolation between interleaved bails with a cinched yoke. FIG. 22 shows an example interleaved hot-key architecture module 2200 with electrical isolation between interleaved bails with the cinched yoke removed.

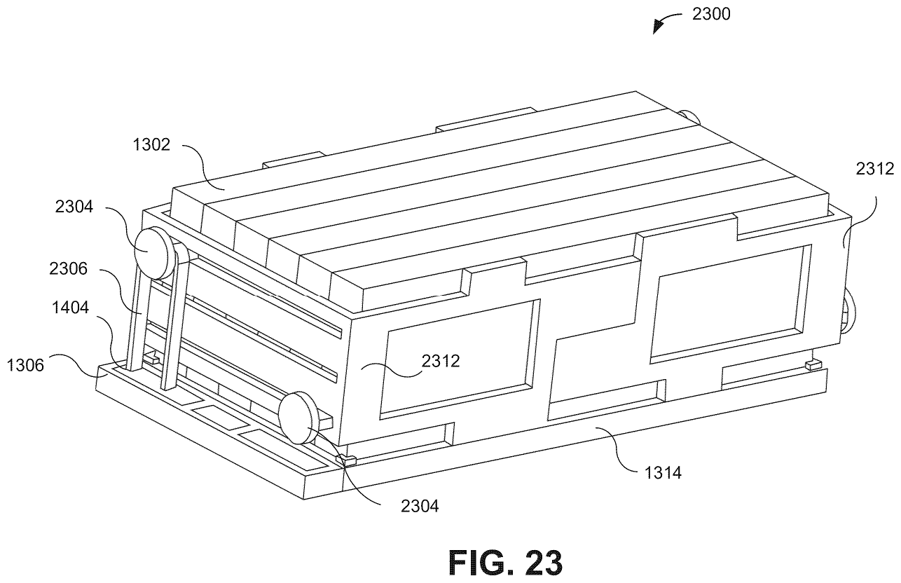

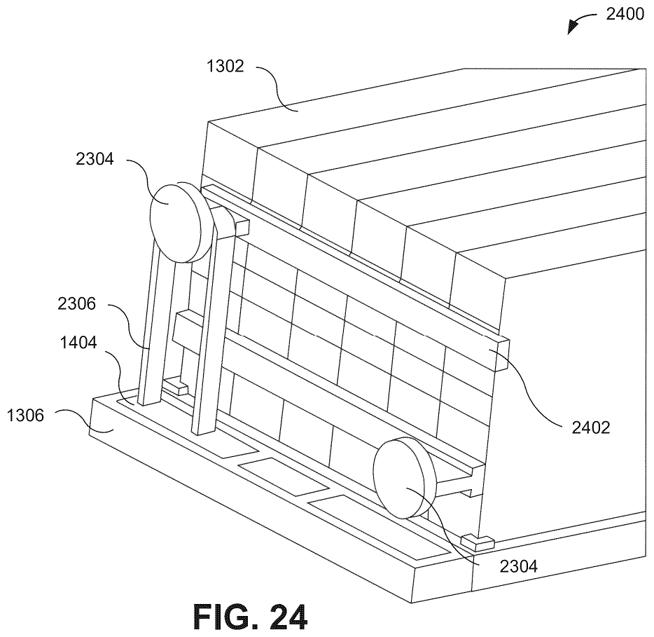

FIGS. 23 and 24 show example tether-key architecture modules 2300 and 2400 consistent with an electromechanical attachment system that secures three-dimensional heterogeneous integration structures to a host using tensioned conductive straps 2306. Such mechanisms provide an electromechanical attachment system that secures 3DHI structures to a host using tensioned conductive straps 2306 that serve as both electrical pathways and compliant mechanical retainers. The system includes hooks 2304 and yokes 2312 mounted along the cube's edges/sides that capture and preload the conductive tethers 2306, which route power and signals from the structure to interposer 1314. Once stretched and latched, the tethers 2306 maintain consistent contact pressure and alignment while allowing controlled mechanical compliance during thermal cycling. Alternatively, yokes 2312 may be removed and hooks 2304 bonded straight to the structure as an additional way of having a complaint system without the thermal stress an enclosure such as yoke 2312 may induce.

Such a configuration enables reliable power and signal transfer without direct soldering, reducing overall thermal stress to the 3DHI stack. Electrical isolation may be achieved through dielectric coatings or segmented routing within strap 2306, and retention can be locked using mechanical clips, UV-cured resin, or adhesive fixation, for example. Tether key systems may be fabricated from laminated foils, braided conductors, or spring-metal composites combined with polymer or ceramic yoke structures. By combining flexible retention and distributed power delivery, the such systems provide reworkable, thermally stable interconnect solutions for high-density 3DHI integration. FIG. 24 shows an example tether-key architecture module 2400 with yoke removed.

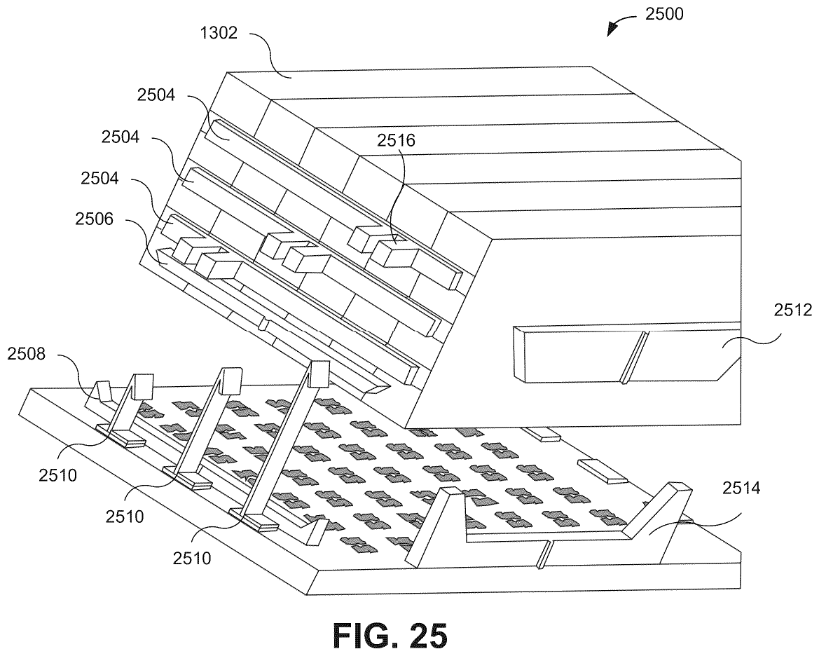

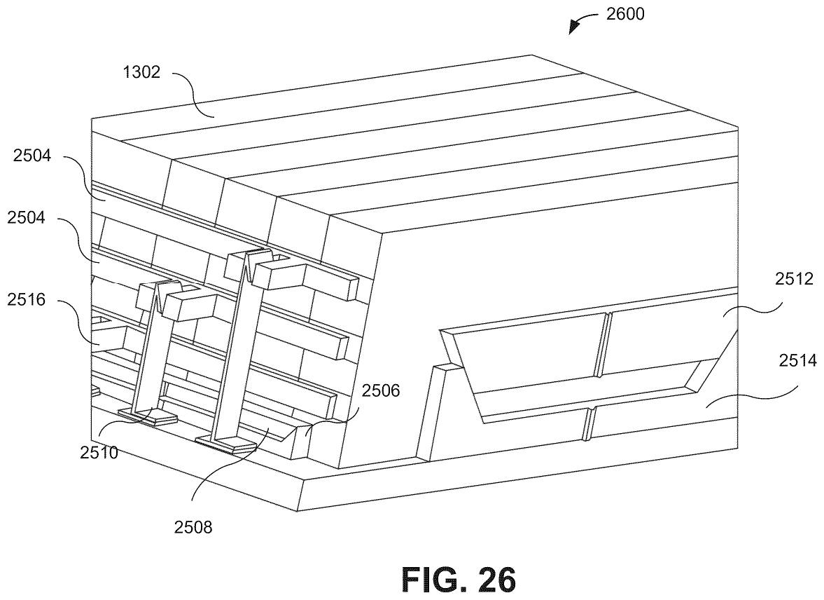

FIGS. 25 and 26 show example quiver-lock architecture modules 2500 and 2600 as a mechanical and electrical attachment architecture for three-dimensional heterogeneous integration structures deploying vertically oriented spring contacts, arrows 2510 to form both mechanical and electrical coupling. In various aspects, arrows 2510 may be soldered to copper landing pads on a host interposer or substrate and aligns with corresponding contact structures 2516 mounted to the cube sidewall. These cube-side structures, or cube-side arrow retainers, may be secured using thermocompression bonding, soldering, or similar metallurgical joining techniques, ensuring robust mechanical and electrical continuity. When the cube is lowered into position, the arrows flex within controlled limits to establish uniform pressure and consistent low-resistance contact.

Vee-Lock alignment guides (2506 and 2508 as well as 2512 and 2414) are optional and may be included to aid in placement and alignment but are not required for operation. The spring contacts may be fabricated from BeCu or comparable high elasticity alloys with dielectric coatings or spacers providing inter-contact isolation. Such a design enables precise, reworkable cube installation, allowing such systems to deliver high-density, thermally compliant interconnect for advanced 3DHI assemblies. FIG. 26 shows an example quiver-lock architecture module 2600 seated in an interposer.

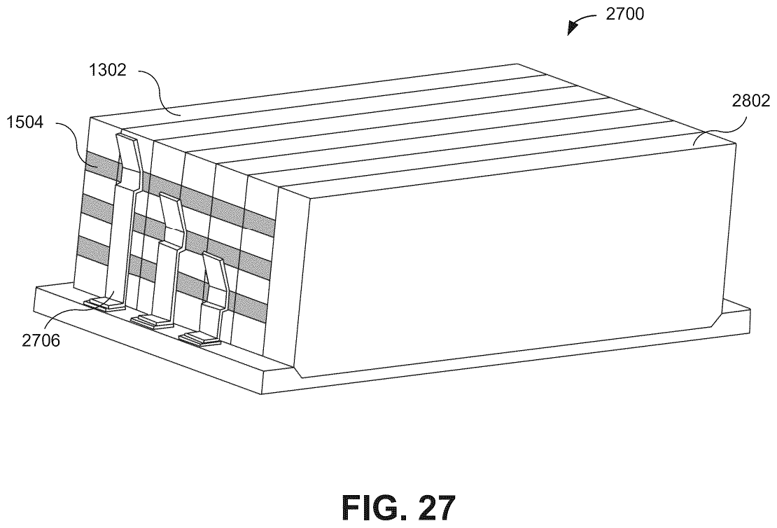

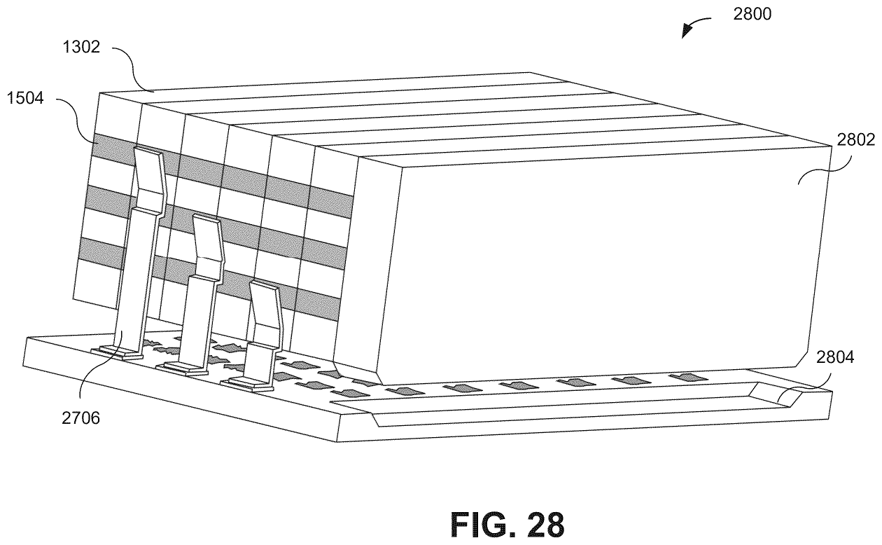

FIGS. 27 and 28 show example slice-lock architecture module 2700 and 2800 as a mechanical alignment and retention architecture that uses an additional semiconductor slice 2802 to create precision mating features between a three-dimensional heterogeneous integration structure and a host interposer or substrate. A dedicated silicon guide slice may be fabricated or diced separately, then bonded or aligned alongside the cube to act as a rigid key structure. Corresponding female recesses 2804 or channels may be etched or machined directly into an interposer or substrate, forming a complementary socket geometry that receives the silicon guide slice 2802. During assembly, the cube may be manually positioned so that the male and female features engage, providing both mechanical registration and edge alignment with micron level accuracy.

This configuration enables highly repeatable cube placement without reliance on external fixtures or high precision equipment. The silicon guide acts as an integrated alignment key, improving mechanical stability and contact consistency between the cube and host contacts. The recesses in the interposer can be formed using plasma etching, deep reactive ion etching (DRIE), or micro-milling, while the guide slice may be fabricated from leftover wafer material or dedicated dummy silicon. Such a design allows scalable implementation across various dimensions and can be combined with spring or other compliant electrical contacts. By incorporating the guide into a silicon stack itself, such systems provides a low-cost, high-precision alignment method for 3DHI structure attachment and reworkable installation. FIG. 28 shows an example slice-lock architecture module 2800 before being seated.

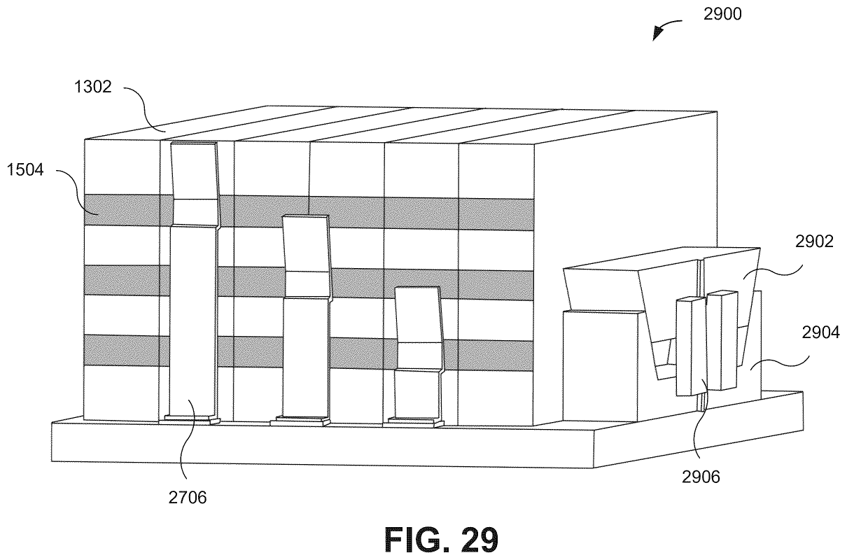

FIG. 29-32 show example vee-lock architecture modules 2900 to 3200 as a mechanical and electrical docking interface designed to align and secure three-dimensional heterogeneous integration structures to a host substrate or interposer. Such V-lock systems provide a mechanical and electrical docking interface designed to align and secure 3DHI structures to a host substrate with sub-micron precision while providing stable, low-resistance electrical connections. Such systems may use ceramic, glass, or silicon V-shaped guides 2902 and 2904 integrated into both the structure and interposer to create self-centering alignment channels that control placement along the X and Y axes. The V-groove guides may be positioned on the structure and interposer using standard pick-and-place assembly tools, after which the structure is manually lowered into alignment tracks. As the structure is seated, compliant side contacts 2706 deflect outward to engage the conductive edge pads, forming friction electrical contact, with lateral cube conductors 1504, while mechanical stops prevent over-travel and misalignment. Mechanical stops 2906 provide alignment and prevent westward drift, while bottom vee structure 2904 prevents eastward drift.

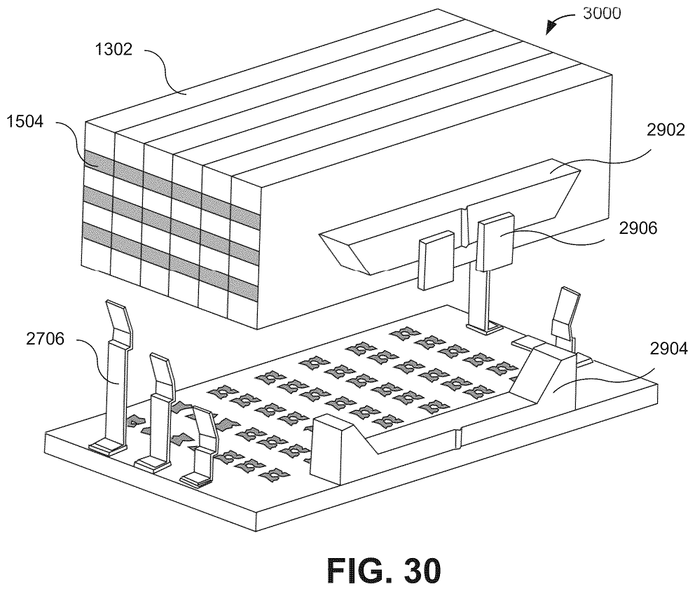

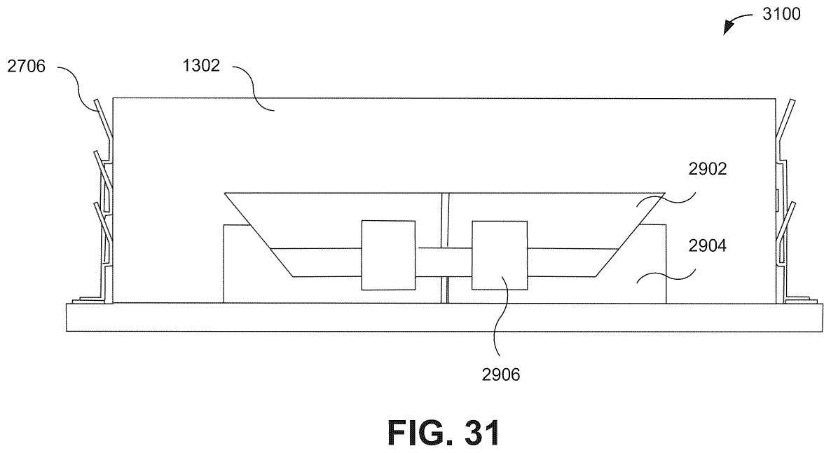

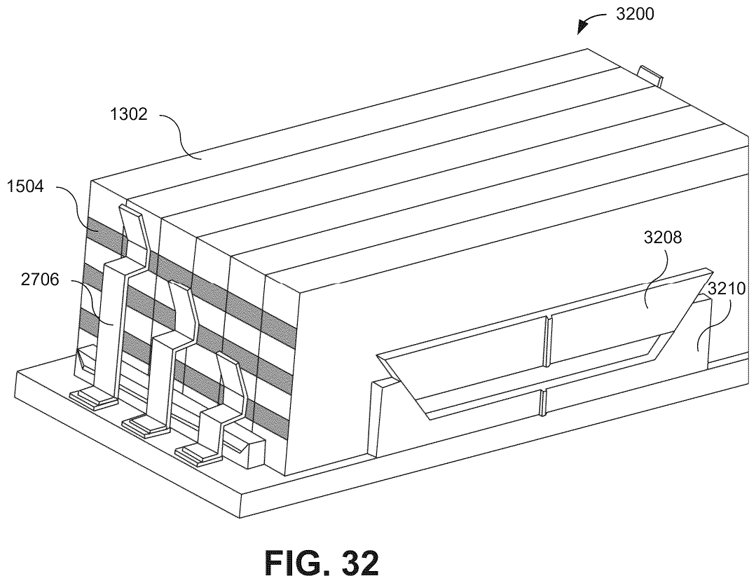

This configuration enables plug-and-play installation without solder reflow, minimizing thermal exposure and simplifying rework. Contacts are soldered or bonded to copper landing pads on the interposer, while dielectric coatings and optional sideband wiring maintain electrical isolation and impedance control. The guides may be attached using die attach film (DAF) or other adhesives or comparable bonding layers and fabricated through precision etching, molding, or micro-machining. By integrating positional alignment, compliant contact engagement, and mechanical retention within a unified structure, such systems provide a scalable, low-stress, and reworkable solution for dense 3DHI attachment. FIG. 30 shows an example vee-lock architecture module 3000 prior to seating. FIG. 31 shows an example vee-lock architecture module 3100 in side view. FIG. 32 shows an example vee-lock architecture module 3200 with optional secondary side alignment mechanism including components 3208 and 3210 for improved alignment as shown.

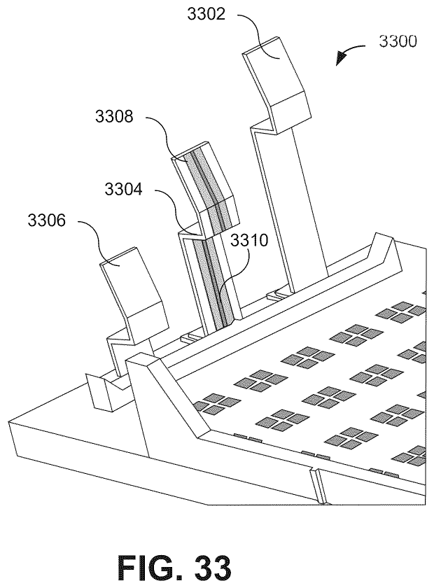

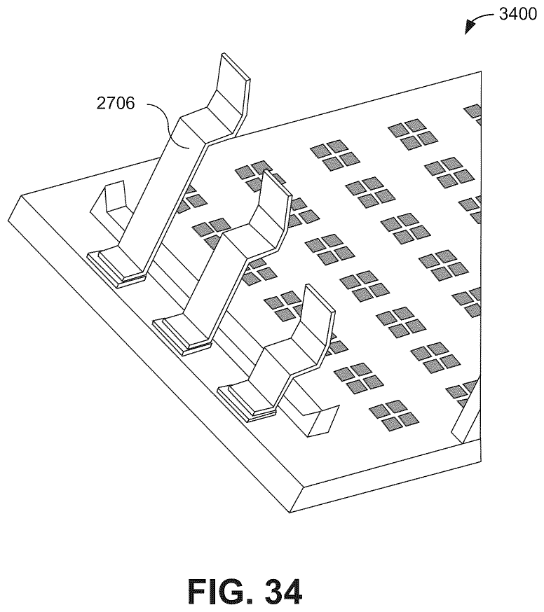

FIG. 33 shows diagram 3300 illustrating example contacts 3310 with reduced impedance at higher frequencies. In various aspects, contacts 3302, 3304, and 3306 may advantageously all be made of a same or similar material, such as for example copper or a copper alloy. For power and ground, having a lower resistance conductor is beneficial to provide adequate current to the three-dimensional cube. In some examples, contacts 3302 and 3306 are power contacts, and a thicker copper or copper alloy contact is desired. However, contact 3304 may be a signal contact for which a lower impedance contact, such as a thin wire may be preferred. In some such instances, a nonconductive strip 3308 may be laid down on top of contact 3304 and then a thin wire deposited or otherwise laid down on top of the nonconductive strip so that a lower impedance contact to the signal interface of a cube may be provided. FIG. 34 shows diagram 3400 illustrating example side contacts 2706 capable of applying steady contact force. To a three-dimensional semiconductor cube.

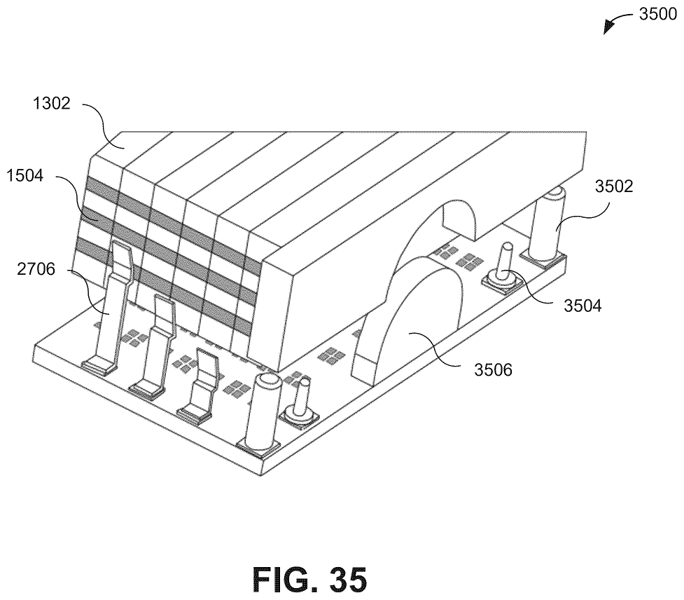

FIGS. 35, 36, and 37 show example Muninn dock systems 3500 to 3700 (or pin-based alignment docking mechanisms) which provide a precision mechanical alignment and electrical docking interface for three-dimensional heterogeneous integration structures, using combination of alignment pins 3502, pin blocks 3702, and keyed guides. The Muninn Dock System provides a precision mechanical alignment and electrical docking interface for 3DHI structures, using combination of alignment pins, pin blocks, and keyed guides 3506 to ensure repeatable and accurate placement of the cube relative to the host interposer. The system supports both key 3506 (Odin's shoulder) and without key configurations, enabling flexible deployment across package types. Alignment is achieved through a multi-tier pin system (course, medium, and fine tolerances) that positions the structure in X, Y, and Z axes.

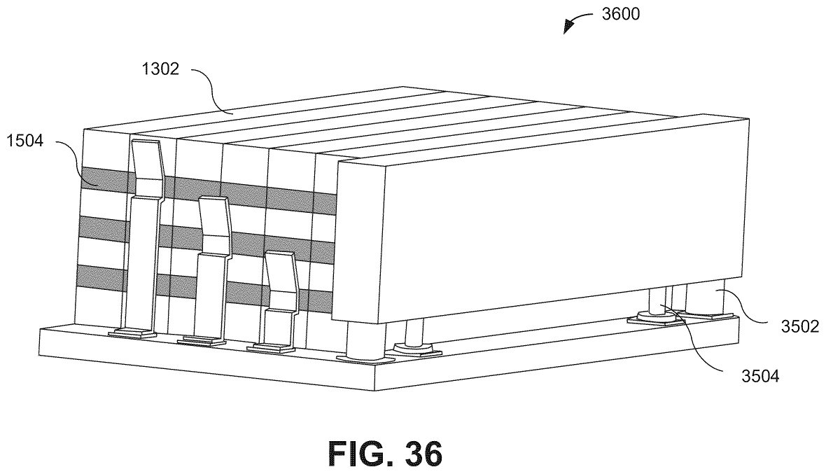

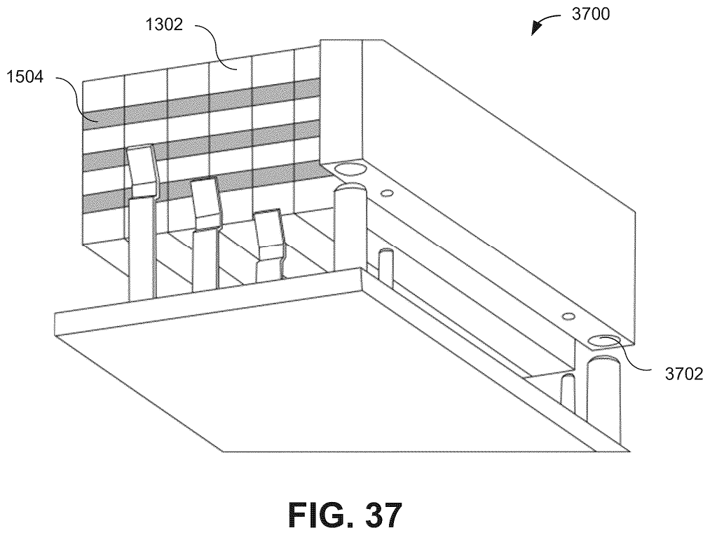

Each alignment pin is formed from BeCu or similar spring alloys, soldered to copper landing pads on interposer. The pin blocks and keys are fabricated from ceramic, silicon, or alumina-based dielectrics, using precision laser or mechanical machining methods to form interlocking geometries. Low-adhesion attachment materials such as DAF or optically aligned adhesives fix the pin blocks to the cube without inducing stress. The Muninn Dock integrates seamlessly with electrical contacts such as BeCu stamp-and-from interconnects, providing both mechanical seating and electrical continuity while supporting hand placement and reworkability for high-density 3DHI arrays. FIG. 36 shows an example Muninn dock system 3600 without a coarse alignment mechanism. FIG. 37 shows an example Muninn dock system 3700 before seating.

Unless explicitly specified, the term “transmit” encompasses both direct (point-to-point) and indirect transmission (via one or more intermediary points). Similarly, the term “receive” encompasses both direct and indirect reception.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “at least one” and “one or more” may be understood to include any integer number greater than or equal to one, i.e., one, two, three, four, [. . . ], etc. The term “a plurality” or “a multiplicity” may be understood to include any integer number greater than or equal to two, i.e. two, three, four, five, [. . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The terms “processor” as used herein may be understood as any kind of technological entity that allows handling of data. The data may be handled according to one or more specific functions that the processor execute. Further, a processor as used herein may be understood as any kind of circuit, e.g., any kind of analog or digital circuit. A processor may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions may also be understood as a processor. It is understood that any two (or more) of the processors detailed herein may be realized as a single entity with equivalent functionality or the like, and conversely that any single processor detailed herein may be realized as two (or more) separate entities with equivalent functionality or the like.

The following examples pertain to aspects of the configuration proposed herein.

Example 1 is a device. The device includes: an interposer comprising a plurality of interposer communication points; a three-dimensional semiconductor cube comprising a plurality of cube communication points corresponding to the plurality of interposer communication points, wherein the three-dimensional semiconductor cube comprises power contacts and a signal contact; a plurality of interposer contacts in communication with the power contacts and the signal contact; and a fastening mechanism to couple the three-dimensional semiconductor cube to the interposer.

In Example 2, the subject matter of Example 1 can optionally include that the three-dimensional semiconductor cube comprises a plurality of semiconductor slices.

In Example 3, the subject matter of Examples 1 or 2 can optionally include that the plurality of interposer communication points comprises a plurality of wireless interposer communication points.

In Example 4, the subject matter of Examples 1 to 3 can optionally include that the plurality of cube communication points comprises a plurality of wireless cube communication points.

In Example 5, the subject matter of Examples 1 to 4 can optionally include that the power contacts and the signal contact comprise lateral cube conductors.

In Example 6, the subject matter of Examples 1 to 5 can optionally include that the plurality of interposer contacts comprises a plurality of bails.

In Example 7, the subject matter of Examples 1 to 6 can optionally include that the plurality of interposer contacts comprises a plurality of interleaved bails.

In Example 8, the subject matter of Examples 1 to 7 can optionally include that the plurality of interposer contacts comprises a plurality of compliant side contacts.

In Example 9, the subject matter of Examples 1 to 8 can optionally include that the fastening mechanism comprises a cauldron comprising solder to fixedly support a plurality of bails affixed to the three-dimensional semiconductor cube.

In Example 10, the subject matter of Examples 1 to 9 can optionally include that the fastening mechanism comprises a plurality of arrows and cube-side arrow retainers.

In Example 11, the subject matter of Examples 1 to 10 can optionally include that the fastening mechanism comprises a plurality of tensioned conductive straps and hooks.

Example 12 is an apparatus. The apparatus includes: a host substrate comprising a plurality of substrate communication points; a three-dimensional semiconductor cube comprising a plurality of cube communication points corresponding to the plurality of interposer communication points; at least two power conductors for coupling power contacts to the three-dimensional semiconductor cube; a signal conductor for coupling a signal contact to the three-dimensional semiconductor cube; a plurality of interposer contacts in communication with the power conductors and the signal conductor; and a fastener for physically coupling the three-dimensional semiconductor cube to the host substrate.

In Example 13, the subject matter of Example 12 can optionally include a yoke for cinching constituent slices of the three-dimensional semiconductor cube.

In Example 14, the subject matter of Examples 12 or 13 can optionally include that the plurality of interposer contacts comprises a signal contact comprising a low impedance conductor for coupling with the signal conductor of the three-dimensional semiconductor cube.

In Example 15, the subject matter of Examples 12 to 14 can optionally include that the host substrate comprises an alignment key.

In Example 16, the subject matter of Examples 12 to 15 can optionally include that the host substrate comprises at least one alignment pin.

In Example 17, the subject matter of Examples 12 to 16 can optionally include that the three-dimensional semiconductor cube comprises a guide slice for aligning the semiconductor cube on the host substrate.

Example 18 is a method. The method includes: forming an interposer comprising a plurality of interposer communication points; forming a three-dimensional semiconductor cube comprising a plurality of cube communication points corresponding to the plurality of interposer communication points; forming at least two power contacts and a signal contact; forming a plurality of interposer contacts in communication with the power contacts and the signal contact; and forming a fastening mechanism to couple the three-dimensional semiconductor cube to the interposer.

In Example 19, the subject matter of Example 18 can optionally include that the fastening mechanism comprises a cauldron comprising solder.

In Example 20, the subject matter of Example 19 can optionally include melting the solder to fixedly support a plurality of bails affixed to the three-dimensional semiconductor cube.

Example 21 is an apparatus. The apparatus includes: a host substrate having a plurality of substrate communication points; a three-dimensional integrated circuit cube having plurality of cube communication points corresponding to each of the plurality of substrate communication points; and at least one latch rotatably coupled to the host substrate and configured to deflect away from the cube based on an insertion of the cube and to return to a grasping position based on the cube being inserted.

In Example 22, the subject matter of Example 21 can optionally include that the latch is a cantilever latch.

In Example 23, the subject matter of Examples 21 or 22 can optionally include that the latch is a snap-fit latch configured to snap back to the grasping position based on the cube being inserted.

In Example 24, the subject matter of Examples 21 to 23 can optionally include that the latch comprises a compliant beam configured to bend outwardly when the cube is inserted and to spring back to hold the cube in place.

In Example 25, the subject matter of Examples 21 to 24 can optionally include that the cube has a top surface and the latch comprises a compliant beam configured to bend outwardly when the cube is inserted and to spring back to hold the cube in place.

In Example 26, the subject matter of Examples 21 to 25 can optionally include that the latch comprises an upper grip configured to grasp a top surface of the cube.

In Example 27, the subject matter of Examples 21 to 26 can optionally include that the cube has a side recess on one or more cube lateral sides and the latch comprises an upper grip configured to grasp the cube at the side recess.

In Example 28, the subject matter of Examples 21 to 27 can optionally include that the latch comprises at least one electrical contact configured to route at least one electrical power or signal trace to the host substrate.

In Example 29, the subject matter of Examples 21 to 28 can optionally include that the host substrate comprises integrated conductive traces configured to route electrical signals associated with the cube wireless communication points to auxiliary device.

In Example 30, the subject matter of Examples 21 to 29 can optionally include that the cube wireless communication points are inductors having one or more inductor coils in electrical communication with a memory cell in the three-dimensional integrated circuit cube.

Example 31 is an apparatus. The apparatus includes: a plurality of three-dimensional integrated circuit cubes each having plurality of cube wireless communication points; a grid of location frames configured to support the plurality of three-dimensional integrated circuit cubes; and a host substrate having a plurality corner locators disposed on an upper surface of the host substrate and configured to support the grid of location frames in an alignment based upon a location of the plurality corner locators, wherein the host substrate has a plurality of substrate wireless communication points corresponding to each of the plurality of cube wireless communication points.

In Example 32, the subject matter of Example 31 can optionally include that the at least one location frames in the grid of location frames comprises a conductive interface configured to provide an electrical interface to at least one of the plurality of three-dimensional integrated circuit cubes.

In Example 33, the subject matter of Examples 31 or 32 can optionally include that a plurality of location frames in the grid of location frames further comprises power and/or signal interfaces to the plurality of three-dimensional integrated circuit cubes.

In Example 34, the subject matter of Examples 31 to 33 can optionally include that the host substrate comprises integrated conductive traces configured to route electrical signals associated with the cube wireless communication points to auxiliary device.

In Example 35, the subject matter of Examples 31 to 34 can optionally include that the cube wireless communication points are inductors having one or more inductor coils in electrical communication with a memory cell in the three-dimensional integrated circuit cube.

Example 36 is an apparatus. The apparatus includes: a host substrate having a plurality of substrate wireless communication points; a three-dimensional integrated circuit cube having a plurality of cube wireless communication points corresponding to each of the plurality of substrate wireless communication points; and at least one selectively applied adhesive layer configured to bond a base of the cube to the host substrate without obstructing the plurality of cube wireless communication points.

In Example 37, the subject matter of Example 36 can optionally include that the selectively applied adhesive layer an insulating adhesive.

In Example 38, the subject matter of Examples 36 or 37 can optionally include that the selectively applied adhesive layer comprises die attach film.

In Example 39, the subject matter of Examples 36 to 38 can optionally include that the host substrate comprises integrated conductive traces configured to route electrical signals associated with the cube wireless communication points to auxiliary device.

In Example 40, the subject matter of Examples 36 to 39 can optionally include that the cube wireless communication points are inductors having one or more inductor coils in electrical communication with a memory cell in the three-dimensional integrated circuit cube.

What is claimed is:

1. A device comprising:
an interposer comprising a plurality of interposer communication points;
a three-dimensional semiconductor cube comprising a plurality of cube communication points corresponding to the plurality of interposer communication points, wherein the three-dimensional semiconductor cube comprises power contacts and a signal contact;
a plurality of interposer contacts in communication with the power contacts and the signal contact; and
a fastening mechanism to couple the three-dimensional semiconductor cube to the interposer.

2. The device of claim 1, wherein the three-dimensional semiconductor cube comprises a plurality of semiconductor slices.

3. The device of claim 1, wherein the plurality of interposer communication points comprises a plurality of wireless interposer communication points.

4. The device of claim 1, wherein the plurality of cube communication points comprises a plurality of wireless cube communication points.

5. The device of claim 1, wherein the power contacts and the signal contact comprise lateral cube conductors.

6. The device of claim 1, wherein the plurality of interposer contacts comprises a plurality of bails.

7. The device of claim 1, wherein the plurality of interposer contacts comprises a plurality of interleaved bails.

8. The device of claim 1, wherein the plurality of interposer contacts comprises a plurality of compliant side contacts.

9. The device of claim 1, wherein the fastening mechanism comprises a cauldron comprising solder to fixedly support a plurality of bails affixed to the three-dimensional semiconductor cube.

10. The device of claim 1, wherein the fastening mechanism comprises a plurality of arrows and cube-side arrow retainers.

11. The device of claim 1, wherein the fastening mechanism comprises a plurality of tensioned conductive straps and hooks.

12. An apparatus comprising:
a host substrate comprising a plurality of substrate communication points;
a three-dimensional semiconductor cube comprising a plurality of cube communication points corresponding to the plurality of substrate communication points;
at least two power conductors for coupling power contacts to the three-dimensional semiconductor cube;
a signal conductor for coupling a signal contact to the three-dimensional semiconductor cube;
a plurality of interposer contacts in communication with the power conductors and the signal conductor; and
a fastener for physically coupling the three-dimensional semiconductor cube to the host substrate.

13. The apparatus of claim 12, further comprising a yoke for cinching constituent slices of the three-dimensional semiconductor cube.

14. The apparatus of claim 12, wherein the plurality of interposer contacts comprises a signal contact comprising a low impedance conductor for coupling with the signal conductor of the three-dimensional semiconductor cube.

15. The apparatus of claim 12, wherein the host substrate comprises an alignment key.

16. The apparatus of claim 12, wherein the host substrate comprises at least one alignment pin.

17. The apparatus of claim 12, wherein the three-dimensional semiconductor cube comprises a guide slice for aligning the three-dimensional semiconductor cube on the host substrate.

18. A method comprising:
forming an interposer comprising a plurality of interposer communication points;
forming a three-dimensional semiconductor cube comprising a plurality of cube communication points corresponding to the plurality of interposer communication points;
forming at least two power contacts and a signal contact;
forming a plurality of interposer contacts in communication with the power contacts and the signal contact; and
forming a fastening mechanism to couple the three-dimensional semiconductor cube to the interposer.

19. The method of claim 18, wherein the fastening mechanism comprises a cauldron comprising solder.

20. The method of claim 19, further comprising melting the solder to fixedly support a plurality of bails affixed to the three-dimensional semiconductor cube.
